(19) United States
(12) Patent Application Publication
(10) Pub. No.: US 2026/0119751 A1
(43) Pub. Date: Apr. 30, 2026

(54) MONITORING OF ELECTRICAL DEVICES WITH PHYSICAL INFORMED NEURAL MACHINE LEARNING

(71) Applicant: Hitachi Energy Ltd, Zürich (CH)

(72) Inventors: Jhelum Chakravorty, Montreal (CA); Pritam Mukherjee, Västerås (SE); Michele Luvisotto, Västerås (SE); Nicolo Ripamonti, Wettingen (CH); Tor Laneryd, Enköping (SE); Clara Abaurrea-Velasco, Dietikon (CH)

(21) Appl. No.: 19/167,217

(22) PCT Filed: Sep. 6, 2023
(86) PCT No.: PCT/EP2023/074494

§ 371 Date: Sep. 19, 2025

(30) Foreign Application Priority Data
Mar. 20, 2023 (EP) 23162860.3

(51) Int. Cl. G06F 30/27

(52) U.S. Cl. CPC G06F 30/27

(57) ABSTRACT

The disclosure provides a method for altering a digital model, the method including: providing the digital model of an electrical device based on boundary conditions of a setup of the electrical device; providing measurement data from a sensor detecting a physical aspect of the electrical device; and altering the digital model by processing the measurement data by a physics-informed neural network, PINN.

### CROSS REFERENCE TO RELATED APPLICATIONS

This application is a 35 U.S.C. § 371 national stage application of International Application No. PCT/EP2023/074494 filed on Sep. 6, 2023, which in turn claims foreign priority to European Patent Application No. 23162860.3 filed on Mar. 20, 2023, the disclosures and content of which are incorporated by reference herein in their entirety.

### TECHNICAL FIELD

The present disclosure relates to a method for altering a digital model and a system for altering a digital model.

### BACKGROUND

Design and operational analysis and diagnostics of complex electrical devices have been a non-trivial problem and mathematical modeling has been proven to be a useful tool in such studies. However, it is not always possible to model the dynamics of complex devices at the sub-component level.

### SUMMARY

The present disclosure relates to a method for altering a digital model, the method comprising: providing the digital model of an electrical device based on (initial) boundary conditions of a setup of the electrical device; providing (first) measurement data from a (first) sensor detecting a physical aspect of the electrical device; and altering the digital model by processing the measurement data by a (first) physics-informed neural network, PINN (to provide an altered digital model).

Along other advantages, this method alters and/or improves the digital model with less data, which might have a poor quality, in a shorter time. Also, less computational resources are needed.

The digital model can be a digital twin of the electrical device. The (initial) digital model can be created from the boundary conditions using a software, as for example a CAD software, a PINN, or similar. The digital model can be created on the same computer system (server, processor, . . . ) on which the other (above mentioned) steps are processed. Alternatively, the digital model can be created on a different computer system and then the digital model is downloaded on another computer system to process the above mentioned steps. The digital model can represent the whole electrical device or a part thereof in sub-component level.

The measurement data can be provided by a sensor which is directly connected to the computer system which performs the above mentioned steps (this can be done in real time). Alternatively, the measurement data can be produced in advance (a time before the other steps are performed) and saved. The computer system performing the above mentioned steps does not need a direct connection to the sensor. This can be advantageous because the computer system might need a lot of space and bringing it to the electrical device would be difficult.

A physical aspect can be a physical property of the electrical device. Examples for physical measures are the size (length) of a wall or wire, the width of a wall, a thickness of a wall, the current through a conductor, a magnetic field strength, a position of a partial discharge and the like.

A physical measure can be something which uses the same unit (like meters, or amperes; meter and ampere is regarded as different units and hence different physical measures, while meter and millimeter is regarded as the same unit and hence represent a same physical measure). Different physical aspects can concern the same physical measure. An example for this can be currents through different conductors, or sizes of different parts, or length and width of an object.

A set of PDEs can be based on physical equations (like Navier-Stokes equations, Maxwell's equations, Ampere's law, heat equations, and so on). Such physical equations often concern one set of physical measures, while not concerning other physical measures.

Various embodiments may implement the following features.

The boundary conditions may be geometrical conditions and constraints. Boundary conditions can additionally or alternatively comprise parameters.

The step of altering the digital model may comprise creating additional boundary conditions and/or adjusting the boundary conditions. Additionally or alternatively, additional parameters can be created and/or adjusted.

Adding boundary conditions and/or parameters can occur in cases where the previous (/initial) digital model was based on an incomplete set of boundary conditions. This can be called “inverse problem”. In this case, the (initial) boundary conditions may only comprise information about parts of the electrical device. For example, the (initial) boundary conditions may only comprise information about outer walls and that a transformer is inside the outer wall. The exact wiring, size and position might not be provided with the initial boundary conditions. In this (inverse problem) case, the altered digital model might also comprise information about the exact wiring, size and position inside the outer walls. In the inverse problem, the PINN may also alter the PDEs while altering the digital model.

In a different case, which may be called “forward problem”, the initial boundary conditions may comprise a full set of information about the electrical device in that all information of the building plan of the electrical device are provided as initial boundary conditions. The boundary conditions may be altered by the PINN in that deviations from the building plan or breakage (or the like) are detected. This may be critical (and then the electrical device needs to be repaired) or it can be not critical (for example in that no danger emanates from it). In some examples, in the forward problem, the PDEs are not changed anymore after the (initial) digital model is provided.

In some examples, the step of altering the digital model by processing the measurement data by the PINN also comprises altering the digital model by processing initial conditions for the digital model by the PINN. Alternatively or additionally, other data can also be considered by the PINN for altering the digital model.

In some examples, the method comprises further: providing of a type of one or more output variables; and providing information of the altered digital model according to the type of one or more output variables. The step of “providing of a type of one or more output variables” can be an input by a user or through an API (Application Programming Interfaces) to another software.

In some examples, the method further comprises: adjusting the electrical device according to the altered digital model.

This may further include checking for a fault and/or breakage in the electrical device according to the altered digital model. Such a check can be done more efficiently because more information about the breakage is known.

Alternatively, the method may further comprise checking the altered digital model (for example by comparing it to (further) measurement data) and correcting the PINN. This trains the PINN and improves it.

In some examples, the electrical device is a transformer, a shunt reactor, a distribution transformer, a circuit breaker, a tap changer, a bushing, or a gas-insulated switchgear, GIS. The electrical device may also be another suitable electromagnetic/electromechanical device.

In some examples, the digital model is an acoustic model, the measurement data are vibration data or acoustic data. In some examples, the digital model is an electromagnetic model, the measurement data are electrical data or magnetic data or electromagnetic data, the sensor is a transient earth voltage sensor or an electrical sensor or magnetic sensor or an electromagnetic sensor. In some examples, the digital model is a stray flux model, the measurement data are stray flux data. In some examples, the digital model is a thermal model, the measurement data are thermal data, the sensor is a thermal camera or a thermocouple. In some examples, the digital model is a fluid-dynamic model. Also, other kinds of digital models, measurement data, and/or sensors, and combinations thereof are possible.

In some examples, the sensor is a fiber optics sensor, a static sensor, a moving sensor, a camera (of visible light, ultraviolet and/or infrared), or a drone.

In some examples, the measurement data are one or more pictures. The measurement data can be in form of a video (of visible light, ultraviolet and/or infrared).

In some examples, the method further comprises: providing second measurement data from a second sensor detecting a second physical aspect of the electrical device; wherein the step of altering the digital model by processing the (first) measurement data by the (first) PINN also comprises altering the digital model by processing the second measurement data by a second PINN.

In some examples, the second physical aspect and the (first) physical aspect concern the same physical measure, and wherein the second PINN is the (first) PINN.

In some examples, the method comprises further (additionally or alternatively to the two paragraphs above): providing third measurement data from a third sensor detecting a third physical aspect of the electrical device, wherein the third physical aspect and the (first) physical aspect concern different physical measure; and further altering the altered digital model by processing the third measurement data by a third PINN, using partial differential equations, PDEs, concerning the third physical aspect, wherein the (first) PINN uses different partial differential equations, PDEs, concerning the (first) physical aspect.

The first and second PINNs may also be one PINN which regards PDEs regarding both (first and third) physical measures.

In some examples, the boundary conditions, on which the (initial) digital model is based, are not a complete representation of the setup of the electrical device.

The present disclosure also relates to a system for altering a digital model, the system comprising: a processor configured to provide the digital model of an electrical device based on boundary conditions of a setup of the electrical device; and a sensor configured to detect a physical aspect of the electrical device to provide measurement data; wherein the processor is further configured to alter the digital model by processing the measurement data by a physics-informed neural network, PINN.

The described advantages of the aspects are neither limiting nor exclusive to the respective aspects. An aspect might have more advantages, not explicitly mentioned.

The exemplary embodiments disclosed herein are directed to providing features that will become readily apparent by reference to the following description when taken in conjunction with the accompany drawings. In accordance with various embodiments, exemplary systems, methods, devices and computer program products are disclosed herein. It is understood, however, that these embodiments are presented by way of example and not limitation, and it will be apparent to those of ordinary skill in the art who read the present disclosure that various modifications to the disclosed embodiments can be made while remaining within the scope of the present disclosure.

The above and other aspects and their implementations are described in greater detail in the drawings, the descriptions, and the claims.

### BRIEF DESCRIPTION OF THE DRAWINGS

FIG. 1 is a schematic illustration showing a system for altering a digital model.

FIG. 2 is a schematic illustration of a PINN architecture.

FIG. 3 is a schematic illustration of an embodiment of a system for altering a digital model.

FIG. 4 is a schematic illustration of an embodiment of a system for altering a digital model.

FIG. 5 is a schematic illustration of a multi-step process to alter a digital model.

FIG. 6 represents a method for altering a digital model.

### DETAILED DESCRIPTION

The disclosure comprises an efficient surrogate model capturing the underlying dynamics that can contribute to the diagnostics, design improvements and fingerprinting and monitoring the operations of an electrical device, improving existing models, understanding uncertainties, benchmarking for monitoring. Physics Informed Machine Learning (PIML) uses specially equipped neural network models, also called Physics-Informed Neural Networks (PINNs), that can estimate the dynamics governed by physics equations such as Partial Differential Equations (PDEs). Having learned the underlying physics, PINNs can render estimations with high accuracy but with less amount of costly input data. Compared to classical solvers, trained PINNs can provide high-quality estimates much faster during inference.

The strength of PINNs of being able to satisfactorily estimate complex dynamics with limited data can be exploited by using it as a surrogate model (digital twin/digital model) of a range of electrical devices during factory tests and operation. In this disclosure, possible embodiments of this emerging technology are described and how one can use this tool in various application scenarios.

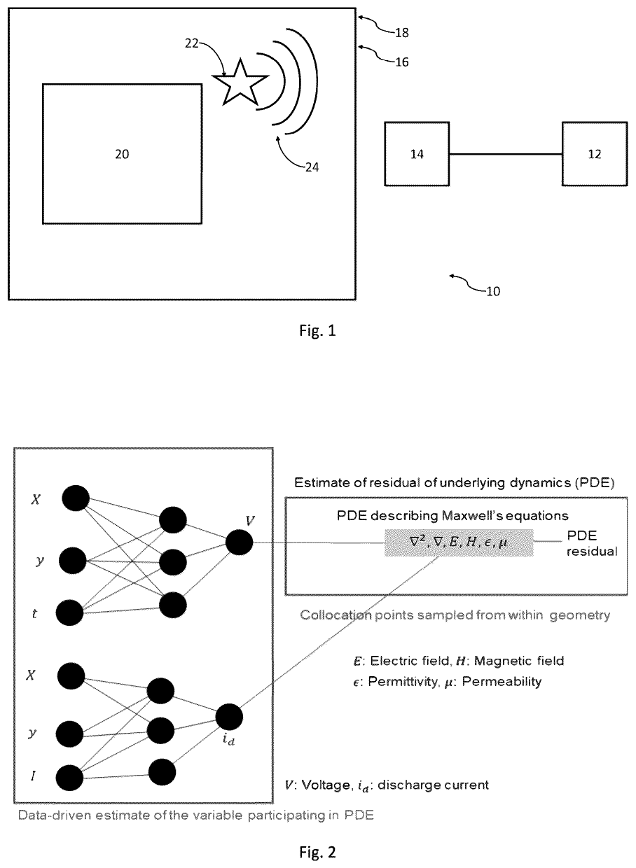

FIG. 1 is a schematic illustration showing a system 10 for altering a digital model. The system 10 comprises a computer system 12 (comprising a processor and other components needed to run the computer system 12, which are not explicitly shown), a sensor 14, and an electrical device 16.

The computer system 12 may have been provided with boundary conditions of the electrical device 16 and may have produced a digital model based on the boundary conditions. Alternatively, the computer system 12 may have been provided with the digital model. The computer system is connected (wired or wirelessly) to the sensor 14. The computer system 12 can be a computer (stationary or mobile), server, computation center (or part thereof), or the like.

The sensor 14 can be attached to the electrical device 16 or positioned with a distance away from the electrical device 16. The sensor can detect a certain physical measure. The sensor 14 is connected to the computer system 12. The sensor 14 can output digital or analog data. The sensor 14 can be any kind of sensor for a desired physical measure. Some examples of possible sensors 14 are: transient earth voltage (TEV) sensor, microphone, transducer, thermometer, electrical sensor, amperemeter, voltmeter, magnetic sensor, electromagnetic sensor, thermal camera, thermocouple, barometer.

The electrical device 16 comprises outer walls 18, and an inner part 20. The inner part 20 represents electrical components. The outer walls 18 are optional and represent some kind of casing. Inside the outer walls 18, there is a source 22 (of some physical measure; for example a partial discharge) shown and effects 24 (same physical measure; for example in the form of electromagnetic waves). The effects 24 can be detected by the sensor 14 if the sensor is configured to sense the corresponding physical measure. The sensor 14 creates measurement data therefrom. These measurement data are then sent to the computer system 12 (and to the processor). There, the digital model is altered by processing the measurement data by a physics-informed neural network (PINN), which runs on the computer system 12 (by the processor).

The source 22 can be of any kind of physical measure which can be detected by a sensor 14. The source 22 can be the size of the outer walls 18, which can be measured in the physical measure of length (for example in meters). Alternatively, the source 22 can be a partial discharge which creates electromagnetic waves, maybe acoustic waves and maybe heat. The electromagnetic waves can be detected by a transient earth voltage (TEV) sensor 14 or the like. Acoustic waves can be detected by a microphone, transducer or some other acoustic sensor 14. Heat can be detected by a thermometer or some other heat sensor 14. The present disclosure is however not limited to these examples.

In one example, the electrical device 16 is a transformer tank. The source 22 is a partial discharge in the electrical device 16 with electromagnet radiation which can induce voltages in the outer walls 18. The sensor 14 is a TEV sensor (which can be mounted on the outer walls 18). The TEV sensor 14 can measure induced voltages in the outer walls 18. The measurement data of the TEV sensor 14 can then be used by the PINN using corresponding partial differential equations (PDE), like Maxwell's equations. In this manner, the altered digital model may show where partial discharge happens in the electrical device 16. Then the electrical device 16 can be fixed or altered.

In another example, acoustic signals from the partial discharge can be detected by a corresponding sensor 14. The PINN can then use acoustic wave equations and the measurement data to create an altered digital model. The same could also work with heat created by the partial discharge. The present disclosure is however not limited to these examples.

In another example, the electrical device 16 comprises a rotating machine. Through stray flux (as source 22), stray flux can be measured on the casing of the rotating machines. With an altered digital model (based on these measured stray flux), faults such as turn-to-turn short circuits, eccentricity in rotor shafts and so on can be found.

In another example, vibration measurements can be used to detect problems in rotating machines. In such a way, location, type, and severity of a damage can be determined through an altered digital model.

In such a manner, it is also possible to detect a fault within the outer wall 18, without opening the electrical device 16. This facilitates the detection. Without the current disclosure, it is quite difficult to detect internal damages such as mechanical deformation, movements, tilting, dislocation, minor inter-turn short circuit in in-service electrical devices (e.g., power transformers). Such damages alter distribution of stray flux which would in turn affect the loss distribution on tank wall.

FIG. 2 is a schematic illustration of a PINN architecture. A mathematical equation describing the underlying system (electric device) dynamics can be used for the PINN to be applied. This may be done with PDEs. The PDEs can be fully known (forward problem) or some components of the PDEs can be unknown or uncertain (inverse problem).

The PDEs are shown in the right box in FIG. 2. An example of Maxwell's equations is shown (for detecting a discharge). Also, different equations can be used as basis for the PDEs. On the left of FIG. 2, a box representing the neural network of the PINN is shown. Sensed measurement data (voltage V and discharge current id) are used by the PINN to find more information on the discharge (location X, y; time t; and current I (in some examples) of the source).

After the PDEs, further parts (some or all) can be defined: Parameters, boundary conditions, initial conditions, input variables and their measurements, output variables, and training and validation. Parameters and boundary conditions are explained above. Initial conditions for temporally dynamic electric devices give values at an initial time (and in some examples give the corresponding initial time) of variables in the dynamics. Input variables and their measurements can be defined in that the PINN knows which kind of measurement data are supplied by the sensor. Further information like sampling rate can also be supplied. By giving the output variable, the PINN system knows which information is requested as output (altered digital model). Output variable(s) can be specified by a software for example through an API, or they can be specified by a user through a graphical user interface. It can also be defined whether an inverse problem or a forward problem is at hand, and/or whether the dynamics (PDEs) can/shall be amended. The PINN system can also be provided with information on whether training or validation is happening. The offline training of the PINN model followed by a validation may be preferred prior to implementing it for online operation. Depending on the availability of the measurement data, a suitable validation method can be recommended, e.g., in forward problem one may apply a direct validation method with ground truth data but for inverse problems one in some examples adopts some indirect method to validate the model due to lack of ground truth data.

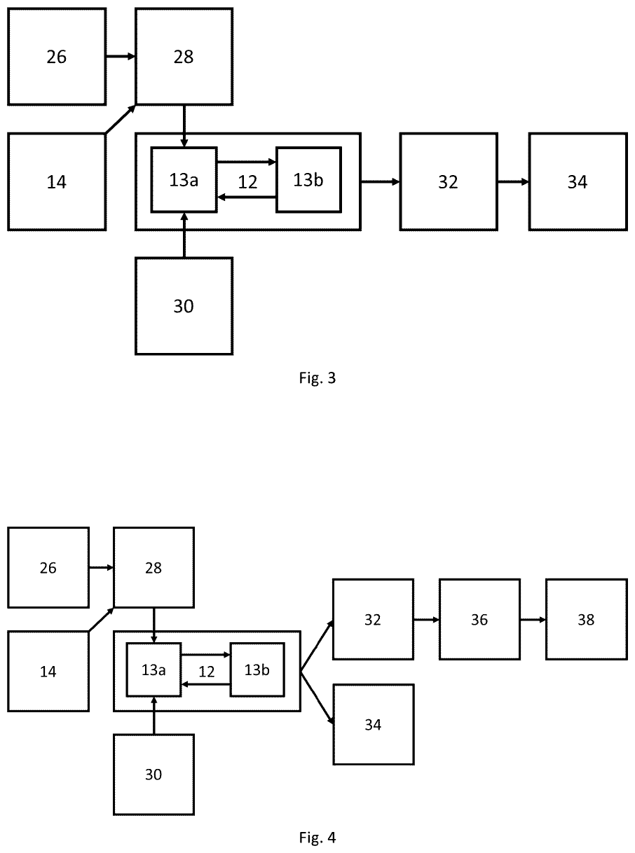

FIGS. 3 and 4 are schematic illustrations of embodiments of a system for altering a digital model. The PINN technology for estimating the dynamics of electrical devices (altering the digital model) can be used for applications such as factory testing (see FIG. 3) and monitoring (see FIG. 4) of the devices in the field, and thus can be used as a service platform. Shown in both figures are a sensor 14, a computational unit with a test room software 26, data preprocessing 28, the computer system 12, design specifications 30, a target platform 32, and a resort 34.

The sensor 14 can detect measurement data from the electrical device 16 as described above.

The test room software 26 may be run on the computer system 12 (where also the PINN runs) or on a different computational unit. The test room software 26 can simulate an electrical device and provide measurement data without needing an actual electrical device 16. The test room software 26 and the sensor 14 can be alternatives.

The data preprocessing 28 is an optional stage, where the measurement data are prepared and/or held until they are used by the PINN.

The computer system 12 implements the PINN 13a interacting with the processor 13b. The computer system 12 (and hence the PINN) can also be supplied with boundary data and other information (parameters, initial conditions) by the design specifications 30. Alternatively, the design specifications 30 may supply the computer system 12 with the initial digital model. The design specifications 30 can for example be an electrical design system (EDS) and/or a mechanical design system (MDS).

The target platform 32 can store the altered digital model. The target platform 32 can be a memory module (hard drive, RAM or similar) of the computer system 12.

The report 34 outputs information, in some examples as specified before (see output variables above). The output can be displaying the information on a display (to a user). The output can be provided to another software, which may use it for further steps.

Specific in FIG. 3 is that the target platform 32 feeds into the report 34. As FIG. 3 represents exemplary factory testing, further information of the electrical device 16 is extracted. From this, the electrical device 16 can be altered, when faults or easily breakable parts are detected.

Specific in FIG. 4 (representing monitoring) are another check on sensor data 36 and an alarm 38. The check on another sensor 36 is done to compare the altered digital model with actual further measurement data. If this comparison confirms a breakage or a critical situation, the alarm 38 will sound. Additionally, a report 34 can be output.

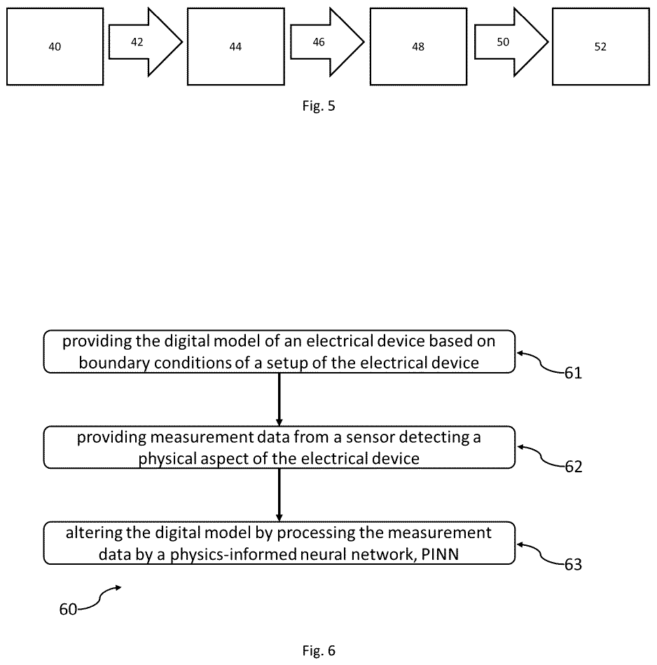

FIG. 5 is a schematic illustration of a multi-step process to alter a digital model. Mostly only one physical measure (one set of measurement data) with a PINN only regarding one specific set of PDE has been considered. It is also possible to consider different physical aspects of the electrical device 16. In some examples, sets of measurement data from different sensors 14 regarding different physical aspects (maybe even different physical measures) are considered. Each set of measurement data may be provided by a corresponding one sensor 14. The multi-step process of FIG. 5 shows how each set of measurement data is considered one after another in consecutive (sub-)steps of altering the digital model.

In step 40, a first set of measurement data form a first sensor is provided (for example transformer winding geometry). Arrow 42 represents a step of using a first set of equations (for example based on Ampere's law) which are used (by a PINN) to alter the digital model. Then box 44 represents a step of providing a second set of measurement data from a second sensor (for example stray flux distribution). This second set of measurement data and the altered digital model from step 42 are used in step 46 to again alter the digital model (by the same or another PINN) based on (the same or another) set of equations (for example Maxwell equations). The resulting (further) altered digital model arrives then at box 48. There a further set of measurement data are provided (for example heat generation in tank during starting). The further altered digital model and the further set of measurement data are then again processed (by the same or another PINN) in step 50 (which for example is based on heat equations). The final product is then output in step 52 (for example a temperature distribution on the tank is output).

Alternatively, the multi-step process can be replaced with one PINN implementing all (different sets of) equations into one combined set of PDEs and processing all measurement data at once.

FIG. 6 represents a method 60 for altering a digital model. Step 61 is providing the digital model of an electrical device based on boundary conditions of a setup of the electrical device. Step 62 is providing measurement data from a sensor detecting a physical aspect of the electrical device. Step 63 is altering the digital model by processing the measurement data by a physics-informed neural network, PINN.

In an embodiment, the boundary conditions are geometrical conditions and constraints.

In an embodiment, the step of altering the digital model comprises creating additional boundary conditions and/or adjusting the boundary conditions.

In an embodiment, the step of altering the digital model by processing the measurement data by the PINN also comprises altering the digital model by processing initial conditions for the digital model by the PINN.

In an embodiment, the method further comprises: providing of a type of one or more output variables; and providing information of the altered digital model according to the type of one or more output variables.

In an embodiment, the method further comprises: adjusting the electrical device according to the altered digital model.

In an embodiment, the electrical device is a transformer, a shunt reactor, a distribution transformer, a circuit breaker, a tap changer, a bushing, or a gas-insulated switchgear, GIS.

In an embodiment, the digital model is an acoustic model, the measurement data are vibration data or acoustic data.

In an embodiment, the digital model is an electromagnetic model, the measurement data are electrical data or magnetic data or electromagnetic data, the sensor is a transient earth voltage sensor or an electrical sensor or magnetic sensor or an electromagnetic sensor.

In an embodiment, the digital model is a stray flux model, the measurement data are stray flux data.

In an embodiment, the digital model is a thermal model, the measurement data are thermal data, the sensor is a thermal camera or a thermocouple.

In an embodiment, the digital model is a fluid-dynamic model.

In an embodiment, the sensor is a fiber optics sensor, a static sensor, a moving sensor, a camera, or a drone.

In an embodiment, the measurement data are one or more pictures.

In an embodiment, the method further comprises: providing second measurement data from a second sensor detecting a second physical aspect of the electrical device, wherein the step of altering the digital model by processing the measurement data by the PINN also comprises altering the digital model by processing the second measurement data by a second PINN.

In an embodiment, the second physical aspect and the physical aspect concern the same physical measure, and wherein the second PINN is the PINN.

In an embodiment, the method further comprises: providing third measurement data from a third sensor detecting a third physical aspect of the electrical device, wherein the third physical aspect and the physical aspect concern different physical measure; and further altering the altered digital model by processing the third measurement data by a third PINN, using partial differential equations, PDEs, concerning the third physical aspect, wherein the PINN uses different partial differential equations, PDEs, concerning the physical aspect.

In an embodiment, the boundary conditions, on which the digital model is based, are not a complete representation of the setup of the electrical device.

While various embodiments of the present disclosure have been described above, it should be understood that they have been presented by way of example only, and not by way of limitation. Likewise, the various diagrams may depict an example architectural or configuration, which are provided to enable persons of ordinary skill in the art to understand exemplary features and functions of the present disclosure. Such persons would understand, however, that the present disclosure is not restricted to the illustrated example architectures or configurations, but can be implemented using a variety of alternative architectures and configurations. Additionally, as would be understood by persons of ordinary skill in the art, one or more features of one embodiment can be combined with one or more features of another embodiment described herein. Thus, the breadth and scope of the present disclosure should not be limited by any of the above-described exemplary embodiments.

It is also understood that any reference to an element herein using a designation such as “first,” “second,” and so forth does not generally limit the quantity or order of those elements. Rather, these designations can be used herein as a convenient means of distinguishing between two or more elements or instances of an element. Thus, a reference to first and second elements does not mean that only two elements can be employed, or that the first element must precede the second element in some manner.

Additionally, a person having ordinary skill in the art would understand that information and signals can be represented using any of a variety of different technologies and techniques. For example, data, instructions, commands, information, signals, bits and symbols, for example, which may be referenced in the above description can be represented by voltages, currents, electromagnetic waves, magnetic fields or particles, optical fields or particles, or any combination thereof.

Various modifications to the implementations described in this disclosure will be readily apparent to those skilled in the art, and the general principles defined herein can be applied to other implementations without departing from the scope of this disclosure. Thus, the disclosure is not intended to be limited to the implementations shown herein, but is to be accorded the widest scope consistent with the novel features and principles disclosed herein, as recited in the claims below.

1-15. (canceled)

16. A method for altering a digital model, the method comprising:
providing the digital model of an electrical device based on boundary conditions of a setup of the electrical device;
providing first measurement data from a first sensor detecting a first physical aspect of the electrical device;
altering the digital model by processing the first measurement data by a first physics-informed neural network, PINN; and
providing second measurement data from a second sensor detecting a second physical aspect of the electrical device, wherein the second measurement data is different to the first measurement data, the second sensor is different to the first sensor, and the second physical aspect is different to the first physical aspect;
wherein the step of altering the digital model by processing the first measurement data by the first PINN also comprises altering the digital model by processing the second measurement data by a second PINN, wherein the second PINN is different to the first PINN; and
wherein the method further comprises: adjusting the electrical device according to the altered digital model.

17. The method according to claim 16, wherein the boundary conditions are geometrical conditions and constraints.

18. The method according to claim 16, wherein the step of altering the digital model comprises creating additional boundary conditions and/or adjusting the boundary conditions.

19. The method according to claim 16, wherein the step of altering the digital model by processing the first measurement data by the first PINN also comprises altering the digital model by processing initial conditions for the digital model by the first PINN.

20. The method according to claim 16, further comprising:
providing of a type of one or more output variables;
providing information of the altered digital model according to the type of one or more output variables; and
outputting information by a report on a display.

21. The method according to claim 16, wherein the electrical device is a transformer, a shunt reactor, a distribution transformer, a circuit breaker, a tap changer, a bushing, or a gas-insulated switchgear, GIS.

22. The method according to claim 16, wherein the digital model is an acoustic model, the first measurement data are vibration data or acoustic data; or
wherein the digital model is an electromagnetic model, the first measurement data are electrical data or magnetic data or electromagnetic data, the first sensor is a transient earth voltage sensor or an electrical sensor or magnetic sensor or an electromagnetic sensor; or
wherein the digital model is a stray flux model, the first measurement data are stray flux data; or
wherein the digital model is a thermal model, the first measurement data are thermal data, the sensor is a thermal camera or a thermocouple; or
wherein the digital model is a fluid-dynamic model.

23. The method according to claim 16, wherein the first sensor is a fiber optics sensor, a static sensor, a moving sensor, a camera, or a drone.

24. The method according to claim 16, wherein the first measurement data are one or more pictures.

25. The method according to claim 16, further comprising:
providing third measurement data from a third sensor detecting a third physical aspect of the electrical device, wherein the third physical aspect and the first physical aspect concern different physical measure; and
further altering the altered digital model by processing the third measurement data by a third PINN, using partial differential equations, PDEs, concerning the third physical aspect, wherein the first PINN uses different partial differential equations, PDEs, concerning the first physical aspect.

26. The method according to claim 16, wherein the boundary conditions, on which the digital model is based, are not a complete representation of the setup of the electrical device.

27. A system for altering a digital model, the system comprising:
a processor configured to provide the digital model of an electrical device based on boundary conditions of a setup of the electrical device; and
a first sensor configured to detect a first physical aspect of the electrical device to provide first measurement data;
wherein the processor is further configured to:
alter the digital model by processing the first measurement data by a first physics-informed neural network, PINN; and
provide second measurement data from a second sensor detecting a second physical aspect of the electrical device, wherein the second measurement data is different to the first measurement data, the second sensor is different to the first sensor, and the second physical aspect is different to the first physical aspect;
wherein the altering the digital model by processing the first measurement data by the first PINN also comprises altering the digital model by processing the second measurement data by a second PINN, wherein the second PINN is different to the first PINN; and
wherein the system further comprises the electrical device configured to be adjusted according to the altered digital model
